(19) United States
(12) Patent Application Publication
(10) Pub. No.: US 2024/0162300 A1
(43) Pub. Date: May 16, 2024

(54) NITRIDE SEMICONDUCTOR DEVICE

(71) Applicant: ROHM CO., LTD., Kyoto-shi (JP)

(72) Inventors: Hirotaka OTAKE, Kyoto-shi (JP); Tsuyoshi TACHI, Kyoto-shi (JP)

(73) Assignee: ROHM CO., LTD., Kyoto-shi (JP)

(21) Appl. No.: 18/393,713

(22) Filed: Dec. 22, 2023

Related U.S. Application Data
(63) Continuation of application No. PCT/JP2022/023968, filed on Jun. 15, 2022.

(30) Foreign Application Priority Data
Jul. 8, 2021 (JP) 2021-113581

(51) Int. Cl. H01L 29/20; H01L 29/778; H01L 29/78

(52) U.S. Cl. CPC H01L 29/2003; H01L 29/7838; H01L 29/778

(57) ABSTRACT

This nitride semiconductor device is provided with: a depletion type transistor which comprises a first gate terminal, a first source terminal and a first drain terminal; and an enhancement type transistor which comprises a second gate terminal, a second source terminal and a second drain terminal. The second drain terminal is connected to the first source terminal; and the second source terminal is connected to the first gate terminal. The depletion type transistor comprises: an electron transit layer which is configured from a nitride semiconductor that contains aluminum in the crystal composition; and an electron supply layer which is formed on the electron transit layer and is configured from a nitride semiconductor that contains a larger amount of aluminum in the composition than the electron transit layer.

### CROSS-REFERENCE TO RELATED APPLICATIONS

This application is a continuation of International Application No. PCT/JP2022/023968, filed Jun. 15, 2022, which claims priority to Japanese Patent Application No. 2021-113581, filed Jul. 8, 2021, the entire contents of each are incorporated herein by reference.

### BACKGROUND

### 1. Field

The present disclosure relates to a nitride semiconductor device.

### 2. Description of Related Art

A nitride semiconductor is currently used to produce a high-electron-mobility transistor (HEMT). When an HEMT is used in a power device, it is desirable from the viewpoint of being fail-safe that the HEMT perform normally-off operation so that the source-drain current path (channel) is disconnected in a zero bias state.

Japanese Laid-Open Patent Publication No. 2015-61265 discloses a cascode transistor in which an enhancement mode silicon metal-oxide-semiconductor field effect transistor (MOSFET) is connected in series to a depletion mode gallium nitride HEMT. In the cascode transistor of Japanese Laid-Open Patent Publication No. 2015-61265, the enhancement mode silicon MOSFET is coupled for the switching of the depletion mode gallium nitride HEMT so that the normally-off operation is performed.

### BRIEF DESCRIPTION OF THE DRAWINGS

FIG. 1 is a schematic circuit diagram of an exemplary nitride semiconductor device according to an embodiment.

FIG. 2 is a schematic cross-sectional view of an exemplary depletion mode transistor according to one aspect of the present disclosure.

FIG. 3 is a schematic cross-sectional view of an exemplary enhancement mode transistor according to one aspect of the present disclosure.

FIG. 4 is a schematic cross-sectional view of an exemplary depletion mode transistor according to another aspect of the present disclosure.

FIG. 5 is a schematic circuit diagram showing an application example of a nitride semiconductor device according to the present disclosure.

FIG. 6 is a schematic circuit diagram showing another application example of a nitride semiconductor device according to the present disclosure.

### DETAILED DESCRIPTION

Embodiments of a nitride semiconductor device according to the present disclosure will be described below with reference to the drawings. In the drawings, elements may not be drawn to scale for simplicity and clarity of illustration. In a cross-sectional view, hatching may be omitted to facilitate understanding. The accompanying drawings only illustrate embodiments of the present disclosure and are not intended to limit the present disclosure.

The following detailed description includes exemplary embodiments of a device, a system, and a method according to the present disclosure. The detailed description is illustrative and is not intended to limit embodiments of the present disclosure or the application and use of the embodiments.

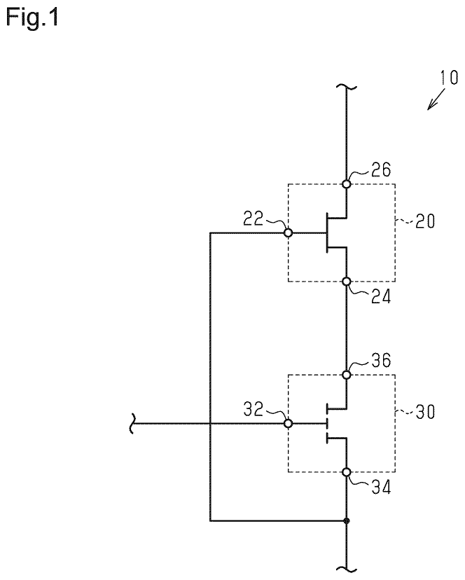

FIG. 1 is a schematic circuit diagram of an exemplary nitride semiconductor device 10 according to an embodiment. The nitride semiconductor device 10 includes a depletion mode transistor 20 and an enhancement mode transistor 30. The depletion mode transistor 20 includes a first gate terminal 22, a first source terminal 24, and a first drain terminal 26. The enhancement mode transistor 30 includes a second gate terminal 32, a second source terminal 34, and a second drain terminal 36. The second drain terminal 36 is connected to the first source terminal 24. The second source terminal 34 is connected to the first gate terminal 22. Thus, the nitride semiconductor device 10 includes a cascode connection of the depletion mode transistor 20 and the enhancement mode transistor 30. The enhancement mode transistor 30, which is included in the cascode connection, enables the nitride semiconductor device 10 to perform a normally-off operation.

The nitride semiconductor device 10, which includes the cascode connection of the depletion mode transistor 20 and the enhancement mode transistor 30, has an on-resistance that corresponds to the sum of the on-resistance of the depletion mode transistor 20 and the on-resistance of the enhancement mode transistor 30. The on-resistance of the depletion mode transistor 20 has a small temperature dependence, which will be described later, and thus decreases the temperature dependence of the overall on-resistance of the nitride semiconductor device 10.

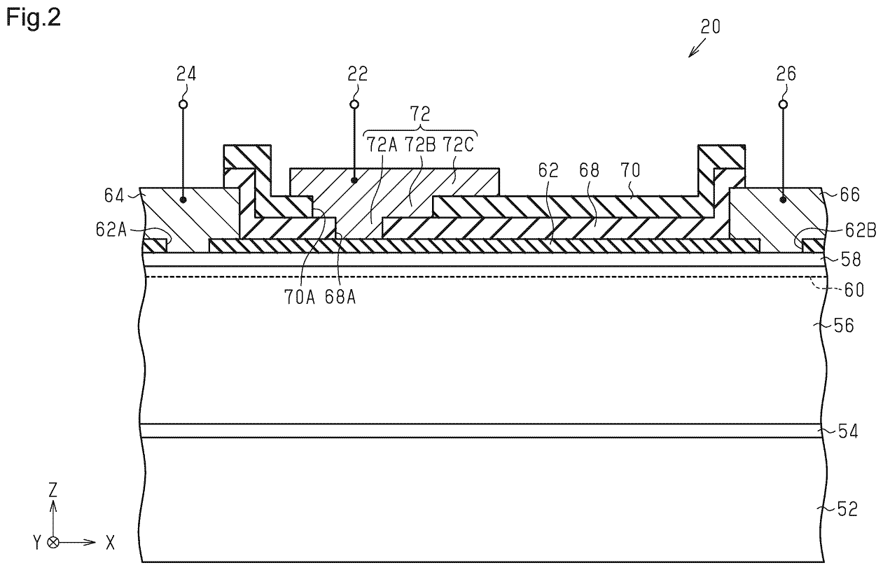

FIG. 2 is a schematic cross-sectional view of an example of the depletion mode transistor 20 according to one aspect of the present disclosure. In an example, the depletion mode transistor 20 is a nitride-semiconductor-based high-electron-mobility transistor (HEMT). The depletion mode transistor 20 includes an electron transit layer 56 composed of a nitride semiconductor including aluminum in a crystal composition and an electron supply layer 58 formed on the electron transit layer 56 and composed of a nitride semiconductor including aluminum having a larger composition than that of the electron transit layer 56.

More specifically, the depletion mode transistor 20 may include a substrate 52, a buffer layer 54 formed on the substrate 52, the electron transit layer 56 formed on the buffer layer 54, and the electron supply layer 58 formed on the electron transit layer 56.

The substrate 52 may be formed of silicon (Si), aluminum nitride (AlN), aluminum oxide (Al₂O₃), or other substrate materials. The substrate 52 may be a qromis' substrate technology (QST) substrate that includes amorphous AlN and Si formed on the surface of the amorphous AlN. The thickness of the substrate 52 may be, for example, in a range of 200 μm to 1500 μm. Among XYZ-axes that are orthogonal to each other shown in FIG. 2, the Z-direction is a direction orthogonal to a surface of the substrate 52 on which a device is formed. In this specification, the thickness of a layer refers to a dimension of the layer in the z-direction unless otherwise explicitly described.

The buffer layer 54 may be arranged between the substrate 52 and the electron transit layer 56 and may be formed of any material that reduces lattice mismatching between the substrate 52 and the electron transit layer 56. The buffer layer 54 may include one or more nitride semiconductor layers, for example, at least one of an aluminum gallium nitride (AlGaN) layer, an aluminum nitride (AlN) layer, and a graded AlGaN layer having different aluminum compositions.

The electron transit layer 56 is composed of a nitride semiconductor including aluminum in a crystal composition. In an example, the electron transit layer 56 may be formed from AlₓGa₁₋ₓN, where 0.1<x<0.2. In an example, x=0.15. In the present disclosure, the phrase “including aluminum in a crystal composition” is intended to exclude a configuration that includes a small amount of aluminum as an impurity. In an example, the phrase “including aluminum in a crystal composition” refers to including at least 10% of aluminum in the composition. However, there is no limitation to such a configuration. The electron transit layer 56 may have a thickness, for example, in a range of 300 nm to 400 nm. In an example, the thickness of the electron transit layer 56 is 350 nm.

The electron supply layer 58 is composed of a nitride semiconductor including aluminum having a larger composition than that of the electron transit layer 56. In an example, the electron supply layer 58 may be formed of Al_{y}Ga_{1-y}N, where 0.25<y<0.4. In an example, y=0.35. Since the electron supply layer 58 includes a larger aluminum composition than the electron transit layer 56, x<y is satisfied. As the aluminum composition increases, the band gap becomes larger. Hence, the electron supply layer 58 has a band gap that is larger than that of the electron transit layer 56. The electron supply layer 58 may have a thickness in a range of 20 nm to 30 nm. In an example, the thickness of the electron supply layer 58 is 25 nm.

The electron transit layer 56 and the electron supply layer 58, which differ from each other in aluminum composition, are composed of nitride semiconductors having different lattice constants. A lattice-mismatching junction between the electron transit layer 56 and the electron supply layer 58 imposes strain on the electron supply layer 58. The strain induces electrons that two-dimensionally spreads in the electron transit layer 56, that is, a two-dimensional electron gas 60 (2DEG). The 2DEG 60 spreads in the electron transit layer 56 at a location close to the heterojunction interface between the electron transit layer 56 and the electron supply layer 58 (for example, approximately a few nanometers away from the interface). The 2DEG 60 is used as a current passage (channel) of the depletion mode transistor 20.

The electron supply layer 58 of the depletion mode transistor 20 may be greater in thickness than a second electron supply layer 108 of the enhancement mode transistor 30, which will be described later. Thus, occurrence of current collapse is limited in the depletion mode transistor 20.

The current collapse refers to an increase in on-resistance when a high voltage is applied between the drain and the source during a deactivated state of the transistor and then the transistor is activated. This may be due to hindrance of generation of two-dimensional electron gas by electrons that are trapped in crystal defect of the transistor or in a layer interface, for example, in the electron transit layer or on the surface of the electron supply layer. Since the electron supply layer 58 of the depletion mode transistor 20 has a relatively large thickness, the surface of the electron supply layer 58 is located distant from the 2DEG 60 so that occurrence of current collapse is limited.

The depletion mode transistor 20 further includes a gate insulation layer 62, a source electrode 64, and a drain electrode 66 formed on the electron supply layer 58.

The gate insulation layer 62 may be formed from any material that insulates the electron supply layer 58 from a gate electrode 72, which will be described later. In an example, the gate insulation layer 62 may include at least one of silicon nitride (SiN) and AlN. In an example, the gate insulation layer 62 may include a SiN layer and an AlN layer formed on the SiN layer.

The gate insulation layer 62 includes a first opening 62A and a second opening 62B exposing the surface of the electron supply layer 58. The source electrode 64 fills the first opening 62A and is in contact with the electron supply layer 58 through the first opening 62A. The drain electrode 66 fills the second opening 62B and is in contact with the electron supply layer 58 through the second opening 62B.

Each of the source electrode 64 and the drain electrode 66 may be formed of one or more metal layers (e.g., any combination of a titanium (Ti) layer, a titanium nitride (TiN) layer, an aluminum (Al) layer, an aluminum-silicon-copper (AlSiCu) alloy layer, and an aluminum-copper (AlCu) alloy layer). In an example, each of the source electrode 64 and the drain electrode 66 may include a Ti layer, a TiN layer formed on the Ti layer, an AlCu layer formed on the TiN layer, and a TiN layer formed on the AlCu layer. Each of the source electrode 64 and the drain electrode 66 is in ohmic contact with the 2DEG 60 present immediately below the electron supply layer 58 through the first opening 62A and the second opening 62B, respectively.

The depletion mode transistor 20 may further include a first passivation layer 68 covering the gate insulation layer 62, the source electrode 64, and the drain electrode 66, a second passivation layer 70 formed on the first passivation layer 68, and a gate electrode 72. The first passivation layer 68 and the second passivation layer 70 partially cover the source electrode 64 and the drain electrode 66.

The first passivation layer 68 includes an opening 68A exposing the gate insulation layer 62. The second passivation layer 70, which is formed on the first passivation layer 68, includes an opening 70A having a larger width than the opening 68A in the X-direction. As viewed from above in the Z-direction, the opening 68A is located at an inner side of the opening 70A. The opening 68A and the opening 70A are located closer to the source electrode 64 than the drain electrode 66.

The first passivation layer 68 and the second passivation layer 70 may be formed from SiN. Although not shown in the drawings, an AlN layer may be formed as an etching stop layer between the first passivation layer 68 and the second passivation layer 70.

The gate electrode 72 is formed on the second passivation layer 70 and fills the opening 68A and the opening 70A. The gate electrode 72 is in contact with the gate insulation layer 62 through the opening 68A and the opening 70A.

As viewed in the Z-direction, the gate electrode 72 may include a gate contact 72A formed in the region of the opening 68A, a first gate field plate 72B formed in the region of the opening 70A excluding the opening 68A, and a second gate field plate 72C formed in a region outside the opening 70A.

The second gate field plate 72C has a larger width than the opening 70A in the X-direction. Thus, the second gate field plate 72C extends closer to the source electrode 64 and the drain electrode 66 than the first gate field plate 72B does. The second gate field plate 72C is separated from the source electrode 64 and the drain electrode 66.

The first gate field plate 72B and the second gate field plate 72C inhibit concentration of electric field, particularly, between the gate and the drain when the gate-source voltage is zero and the drain-source voltage is relatively high.

When the gate-source voltage is zero and the drain-source voltage is relatively high, electric field is also applied to the first passivation layer 68 and/or the second passivation layer 70, located under the first gate field plate 72B and the second gate field plate 72C. The electric field increases as the drain electrode 66 becomes closer.

In the example shown in FIG. 2, the first passivation layer 68 and the second passivation layer 70 are located under the second gate field plate 72C, which is located relatively close to the drain electrode 66. Under the second gate field plate 72C, the total thickness of the passivation layers is increased by the thickness of the second passivation layer 70. This improves the resistance of the first passivation layer 68 and the second passivation layer 70 to dielectric breakdown.

The gate electrode 72, the source electrode 64, and the drain electrode 66 are respectively connected to the first gate terminal 22, the first source terminal 24, and the first drain terminal 26, which are shown in FIG. 1.

As described above, the depletion mode transistor 20 includes the electron transit layer 56 composed of a nitride semiconductor including aluminum in a crystal composition and the electron supply layer 58 formed on the electron transit layer 56 and composed of a nitride semiconductor including aluminum having a larger composition than that of the electron transit layer 56. In this configuration, the 2DEG 60 receives a smaller effect from decreases in electron movement caused by lattice oscillation than in a configuration in which the electron transit layer 56 does not include aluminum in a crystal composition. This decreases the temperature dependence of the on-resistance. The on-resistance of the depletion mode transistor 20 is less temperature-dependent than, for example, that of a GaN channel HEMT in which a gallium nitride (GaN) layer is an electron transit layer.

From the viewpoint of ensuring a normally-off operation with the enhancement mode transistor 30 while increasing the breakdown voltage of the nitride semiconductor device 10 with the depletion mode transistor 20, the drain-source voltage of the depletion mode transistor 20 may have a larger maximum rating than that of the enhancement mode transistor 30. From the same viewpoint, the depletion mode transistor 20 may have an on-resistance that is larger than that of the enhancement mode transistor 30. In an example, the on-resistance of the depletion mode transistor 20 may be more than ten times greater than the on-resistance of the enhancement mode transistor 30. In such a case, the proportion of the on-resistance of the depletion mode transistor 20 to the on-resistance of the nitride semiconductor device 10 is greater than or equal to 90%.

In an example, the drain-source voltage of the depletion mode transistor 20 may have a maximum rating that is greater than or equal to 500 V. The drain-source voltage of the enhancement mode transistor 30 may have a maximum rating that is greater than or equal to 30 V. In an example, the drain-source voltage of the enhancement mode transistor 30 may have a maximum rating that is less than or equal to 100 V.

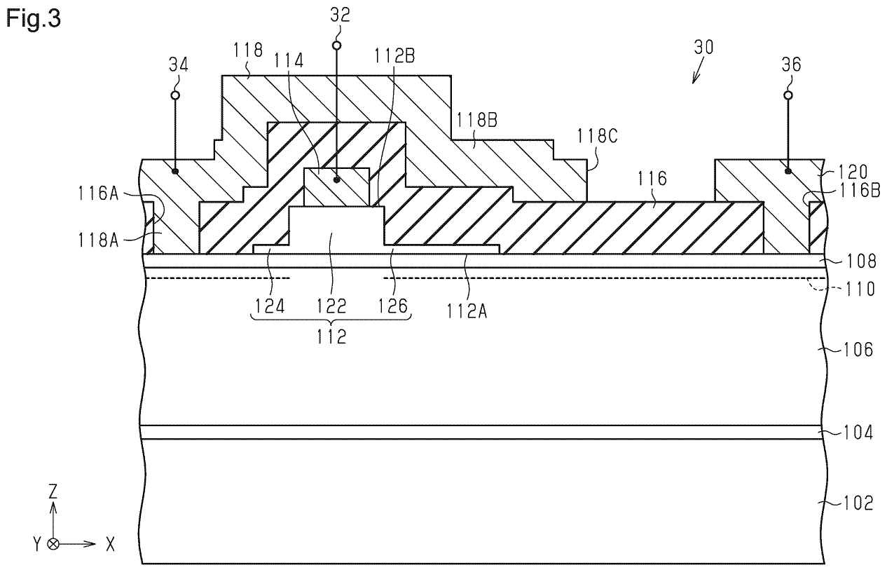

FIG. 3 is a schematic cross-sectional view of an example of an enhancement mode transistor 30 according to one aspect of the present disclosure. The enhancement mode transistor 30 is a nitride-semiconductor-based HEMT.

The enhancement mode transistor 30 may include a substrate 102, a buffer layer 104 formed on the substrate 102, an electron transit layer 106 formed on the buffer layer 104, and an electron supply layer 108 formed on the electron transit layer 106. The buffer layer 104 may also be referred to as a second buffer layer so as to be distinguished from the buffer layer 54 of the depletion mode transistor 20. The electron transit layer 106 may also be referred to as a second electron transit layer so as to be distinguished from the electron transit layer 56 of the depletion mode transistor 20. The electron supply layer 108 may also be referred as a second electron supply layer so as to be distinguished from the electron supply layer 58 of the depletion mode transistor 20.

The substrate 102 may be formed of silicon (Si), silicon carbide (SiC), GaN, sapphire, or other substrate materials. In an example, the substrate 102 is a Si substrate.

The substrate 102 of the enhancement mode transistor 30 may be formed from the same material as that of the substrate 52 of the depletion mode transistor 20 or may be formed from a material differing from that of the substrate 52 of the depletion mode transistor 20. In an example in which the substrate 52 and the substrate 102 are formed from the same material, the substrate 52 and the substrate 102 may be a Si substrate. In an example in which the substrate 52 and the substrate 102 are formed from different materials, the substrate 52 may be a semiconductor substrate including Al, and the substrate 102 may be a Si substrate.

The thickness of the substrate 102 may be, for example, in a range of 200 μm to 1500 μm. Among XYZ-axes that are orthogonal to each other shown in FIG. 3, the Z-direction is a direction orthogonal to a surface of the substrate 102 on which a device is formed.

The buffer layer 104 may be arranged between the substrate 102 and the electron transit layer 106 and may be formed of any material that reduces lattice mismatching between the substrate 102 and the electron transit layer 106. The buffer layer 104 may include one or more nitride semiconductor layers, for example, at least one of an AlN layer, an AlGaN layer, and a graded AlGaN layer including different aluminum compositions. For example, the buffer layer 104 may include a single AlN layer, a single AlGaN layer, a layer having a superlattice structure of AlGaN/GaN, a layer having a superlattice structure of AlN/AlGaN, or a layer having a superlattice structure of AlN/GaN.

In an example, the buffer layer 104 may include a first buffer layer that is an AlN layer formed on the substrate 102 and a second buffer layer that is an AlGaN layer formed on the AlN layer. In an example, the first buffer layer may be an AlN layer having a thickness of 200 nm. In an example, the second buffer layer may have a structure in which multiple AlGaN layers are stacked. To inhibit current leakage of the buffer layer 104, a portion of the buffer layer 104 may be doped with an impurity so that the buffer layer 104 becomes semi-insulating. In this case, the impurity is, for example, carbon (C) or iron (Fe). The concentration of the impurity may be, for example, greater than or equal to 4×10¹⁶ cm⁻³.

The electron transit layer 106 is composed of a nitride semiconductor and may be, for example, a GaN layer. The electron transit layer 106 may be composed of a nitride semiconductor having a band gap that is smaller than that of the electron transit layer 56 of the depletion mode transistor 20. The thickness of the electron transit layer 106 may be, for example, in a range of 300 nm to 2 μm, and more preferably, in a range of 300 nm to 400 nm. In an example, the thickness of the electron transit layer 106 is 350 nm.

To inhibit current leakage from the electron transit layer 106, a portion of the electron transit layer 106 may be doped with an impurity so that the electron transit layer 106 excluding an outer layer region is semi-insulating. In this case, the impurity is, for example, C. The concentration of the impurity may be, for example, greater than or equal to 1×10¹⁹ cm⁻³ at a peak concentration. More specifically, the electron transit layer 106 may include GaN layers having different impurity concentrations, for example, a C-doped GaN layer and a non-doped GaN layer. The C concentration in the C-doped GaN layer may be in a range of 9×10¹⁸ cm⁻³ to 9×10¹⁹ cm⁻³.

The electron supply layer 108 is composed of a nitride semiconductor having a band gap that is larger than that of the electron transit layer 106 and may be, for example, an AlGaN layer. The band gap increases as the Al composition increases. Therefore, the electron supply layer 108, which is an AlGaN layer, has a larger band gap than the electron transit layer 106, which is a GaN layer. In an example, the electron supply layer 108 is formed from Al_{z}Ga_{1-z}N, where 0.1<z<0.4, and more preferably, 0.2<z<0.3. In an example, z=0.25. The electron supply layer 108 may have a thickness in a range of 5 nm to 20 nm. In an example, the thickness of the electron supply layer 108 may be in a range of 8 nm to 15 nm.

The electron transit layer 106 and the electron supply layer 108 are formed from nitride semiconductors having different lattice constants. A lattice-mismatching junction between the electron transit layer 106 and the electron supply layer 108 imposes strain on the electron supply layer 108. The strain induces a two-dimensional electron gas 110 (2DEG) in the electron transit layer 106. The 2DEG 110 spreads in the electron transit layer 106 at a location close to the heterojunction interface between the electron transit layer 106 and the electron supply layer 108 (for example, approximately a few nanometers away from the interface). The 2DEG 110 is used as a current passage (channel) of the enhancement mode transistor 30.

The enhancement mode transistor 30 further includes a gate layer 112 formed on the electron supply layer 108, a gate electrode 114 formed on the gate layer 112, a passivation layer 116 covering the electron supply layer 108, the gate layer 112, and the gate electrode 114 and including a first opening 116A and a second opening 116B, a source electrode 118 in contact with the electron supply layer 108 through the first opening 116A, and a drain electrode 120 in contact with the electron supply layer 108 through the second opening 116B.

The gate layer 112 is formed on a portion of the electron supply layer 108 and composed of a nitride semiconductor including an acceptor impurity. The gate layer 112 may be formed of any material having a band gap that is smaller than that of the electron supply layer 108, which is, for example, an AlGaN layer. In an example, the gate layer 112 is a GaN layer (p-type GaN layer) doped with an acceptor impurity. The acceptor impurity may include at least one of zinc (Zn), magnesium (Mg), and carbon (C). The maximum concentration of the acceptor impurity in the gate layer 112 is, for example, in a range of 7×10¹⁸ cm⁻³ to 1×10²⁰ cm⁻³.

The gate layer 112 includes a bottom surface 112A in contact with the electron supply layer 108 and an upper surface 112B opposite to the bottom surface 112A. The gate electrode 114 is formed on the upper surface 112B of the gate layer 112. In the ZX-plane shown in FIG. 3, the gate layer 112 may have a cross section that is rectangular, trapezoidal, or ridged.

In the example shown in FIG. 3, the gate layer 112 includes a ridge 122 including the upper surface 112B on which the gate electrode 114 is formed and two extensions 124 and 126 (first extension 124 and second extension 126) extending outward from the ridge 122 in plan view. The “plan view” refers to an upper view of the enhancement mode transistor 30 in the Z-direction.

In plan view, the first extension 124 extends from the ridge 122 toward the first opening 116A. The first extension 124 is separated from the first opening 116A.

In plan view, the second extension 126 extends from the ridge 122 toward the second opening 116B. The second extension 126 is separated from the second opening 116B.

The ridge 122 is located between the first extension 124 and the second extension 126 and formed integrally with the first extension 124 and the second extension 126. Since the gate layer 112 includes the first extension 124 and the second extension 126, the bottom surface 112A may be greater in area than the upper surface 112B. In the example shown in FIG. 3, the second extension 126 extends longer than the first extension 124 outward from the ridge 122 in plan view.

The ridge 122 corresponds to a relatively thick portion of the gate layer 112 and may have a thickness in a range of 80 nm to 150 nm. The thickness of the gate layer 112, particularly, the ridge 122, may be determined taking into consideration parameters including the gate threshold voltage. In an example, the thickness of the gate layer 112 (the ridge 122) is greater than 110 nm.

Each of the first extension 124 and the second extension 126 is smaller in thickness than the ridge 122. In an example, the thickness of each of the first extension 124 and the second extension 126 is less than or equal to one-half of the thickness of the ridge 122.

In the example shown in FIG. 3, each of the first extension 124 and the second extension 126 is a flat portion having a substantially constant thickness. In this specification, “substantially constant thickness” refers to a thickness within a manufacturing variation range (for example, 20%). Alternatively, each of the first extension 124 and the second extension 126 may include a tapered portion having a thickness that gradually decreases as the ridge 122 becomes farther away in a region abutting the ridge 122 and a flat portion in a region separated from the ridge 122 by a predetermined distance. In an example, the flat portion may have a thickness in a range of 5 nm to 25 nm.

The gate electrode 114 is formed on the upper surface 112B of the gate layer 112. In other words, since the ridge 122 includes the upper surface 112B of the gate layer 112, the gate electrode 114 is formed on the ridge 122 of the gate layer 112. The gate electrode 114 is formed of one or more metal layers, which is, for example, a TiN layer. Alternatively, the gate electrode 114 may include a first metal layer composed of Ti and a second metal layer arranged on the first metal layer and composed of TiN. The gate electrode 114 may have a thickness that is, for example, greater than or equal to 50 nm and less than or equal to 200 nm. The gate electrode 114 forms a Schottky junction with the gate layer 112.

The passivation layer 116 covers the electron supply layer 108, the gate layer 112, and the gate electrode 114 and includes the first opening 116A and the second opening 116B.

The first opening 116A and the second opening 116B of the passivation layer 116 are separated from the gate layer 112. The gate layer 112 is arranged between the first opening 116A and the second opening 116B. More specifically, the gate layer 112 may be arranged between the first opening 116A and the second opening 116B at a position closer to the first opening 116A than to the second opening 116B. The passivation layer 116 extends on the upper surface of the electron supply layer 108, the side surface and the upper surface 112B of the gate layer 112, and the side surface and the upper surface of the gate electrode 114. Thus, the passivation layer 502 includes a non-flat surface.

The source electrode 118 and the drain electrode 120 may be composed of one or more metal layers (e.g., any combination of a Ti layer, a TiN layer, an Al layer, an AlSiCu layer, an AlCu layer, and the like). At least a portion of the source electrode 118 fills the first opening 116A. At least a portion of the drain electrode 120 fills the second opening 116B. Each of the source electrode 118 and the drain electrode 120 is in ohmic contact with the 2DEG 110 present immediately below the electron supply layer 108 through the first opening 116A and the second opening 116B, respectively.

The source electrode 118 includes a source contact 118A filling the first opening 116A and a source field plate 118B covering the passivation layer 116. The source field plate 118B is continuous with the source contact 118A and is formed integrally with the source contact 118A. In plan view, the source field plate 118B includes an end 118C located between the second opening 116B and the gate layer 112 in plan view. The source field plate 118B extends from the source contact 118A to the end 118C along the surface of the passivation layer 116 toward the drain electrode 120 but is separated from the drain electrode 120. Since the source field plate 118B extends along the non-flat surface of the passivation layer 116, the source field plate 118B includes a non-flat surface in the same manner. In a state in which no gate voltage is applied to the gate electrode 114, that is, in the zero bias state, when a drain voltage is applied to the drain electrode 120, the source field plate 118B reduces the concentration of electric field in the vicinity of the end of the gate electrode 114.

The gate electrode 114, the source electrode 118, and the drain electrode 120 are respectively connected to the second gate terminal 32, the second source terminal 34, and the second drain terminal 36, which are shown in FIG. 1.

As described above, when the enhancement mode transistor 30 is a nitride-semiconductor-based high-electron-mobility transistor (HEMT), the maximum rating of the gate-source voltage of the enhancement mode transistor 30 may be greater than or equal to 8 V.

In the example described with reference to FIG. 3, the enhancement mode transistor 30 is a nitride-semiconductor-based HEMT. Alternatively, the enhancement mode transistor 30 may be a silicon-based metal-oxide-semiconductor field effect transistor (silicon MOSFET). The enhancement mode transistor 30 may be selected from any device that achieves a normally-off operation.

The temperature dependence of the on-resistance of the enhancement mode transistor 30 may be greater than that of the depletion mode transistor 20. However, the proportion of the on-resistance of the depletion mode transistor 20 to the on-resistance of the entire nitride semiconductor device 10 is relatively small (e.g., less than 10%). This has only a negligible effect on the temperature dependence.

Operation

The operation of the nitride semiconductor device 10 of the present embodiment will be described below.

The nitride semiconductor device 10 includes a cascode connection of the depletion mode transistor 20 and the enhancement mode transistor 30. The on-resistance of the nitride semiconductor device 10, which includes the cascode connection of the depletion mode transistor 20 and the enhancement mode transistor 30, corresponds to the sum of the on-resistance of the depletion mode transistor 20 and the on-resistance of the enhancement mode transistor 30. The depletion mode transistor 20, the on-resistance of which has a small temperature dependence, is used to decrease the temperature dependence of the overall on-resistance of the nitride semiconductor device 10 while ensuring the normally-off operation.

The depletion mode transistor 20 includes the electron transit layer 56 composed of a nitride semiconductor including aluminum in a crystal composition and the electron supply layer 58 formed on the electron transit layer 56 and composed of a nitride semiconductor including aluminum having a larger composition than that of the electron transit layer 56. In this configuration, the 2DEG 60 receives a smaller effect from decreases in electron movement caused by lattice oscillation than in a configuration in which the electron transit layer 56 does not include aluminum in a crystal composition. This decreases the temperature dependence of the on-resistance.

In particular, when the on-resistance of the depletion mode transistor 20 has a large proportion to the on-resistance of the nitride semiconductor device 10, the temperature dependence of the on-resistance of the nitride semiconductor device 10 is improved effectively by decreasing the temperature dependence of the on-resistance of the depletion mode transistor 20.

Advantages

The nitride semiconductor device 10 of the first embodiment has the following advantages.

(1) The nitride semiconductor device 10 includes a cascode connection of the depletion mode transistor 20 and the enhancement mode transistor 30. The depletion mode transistor 20 includes the electron transit layer 56 composed of a nitride semiconductor including aluminum in a crystal composition and the electron supply layer 58 formed on the electron transit layer 56 and composed of a nitride semiconductor including aluminum having a larger composition than that of the electron transit layer 56.

With this structure, decreases in electron movement caused by lattice oscillation have a smaller effect on the 2DEG 60, which is generated in the depletion mode transistor 20. This decreases the temperature dependence of the on-resistance of the depletion mode transistor 20. As a result, while the normally-off operation is ensured, the temperature dependence of the overall on-resistance of the nitride semiconductor device 10 is reduced.

(2) The enhancement mode transistor 30 includes the second electron transit layer 106 composed of a nitride semiconductor having a band gap that is smaller than that of the electron transit layer 56 of the depletion mode transistor 20, the second electron supply layer 108 formed on the second electron transit layer 106 and composed of a nitride semiconductor having a band gap that is larger than that of the second electron transit layer 106, and the gate layer 112 formed on a portion of the second electron supply layer 108 and composed of a nitride semiconductor including an acceptor impurity.

With this structure, each of the depletion mode transistor 20 and the enhancement mode transistor 30 is a nitride semiconductor HEMT that does not include an anti-parallel pn-diode and thus demonstrates satisfactory reverse recovery at high temperatures.

(3) The electron supply layer 58 of the depletion mode transistor 20 may be greater in thickness than the second electron supply layer 108 of the enhancement mode transistor 30.

With this structure, in the depletion mode transistor 20, the surface of the electron supply layer 58 is located distant from the 2DEG 60. This limits occurrence of current collapse.

(4) The gate layer 112 may include the ridge 122 including the upper surface 112B on which the gate electrode 114 is formed and the extension 126 (and/or 124) extending outward from the ridge 122 in plan view and having a thickness that is less than or equal to one-half of the thickness of the ridge 122.

With this structure, the area of the bottom surface 112A of the gate layer 112 is increased by an amount corresponding to the extension 126 (and/or 124) as compared to a structure in which the gate layer 112 includes only the ridge 122. This reduces the density of holes accumulated in the interface between the gate layer 112 and the electron supply layer 108, thereby reducing the leakage of current.

(5) The gate-source voltage of the enhancement mode transistor 30 may have a maximum rating that is greater than or equal to 8 V.

With this structure, the gate-source voltage of the enhancement mode transistor 30, the gate of which is configured to be driven, has a relatively high maximum rating. This increases the reliability of operation of the nitride semiconductor device 10.

(6) Each of the depletion mode transistor 20 and the enhancement mode transistor 30 may include a Si substrate.

With this structure, the depletion mode transistor 20 and the enhancement mode transistor 30 are manufactured using a Si substrate. This reduces the manufacturing cost of the nitride semiconductor device 10.

(7) The enhancement mode transistor 30 may include a Si substrate. The depletion mode transistor 20 may include a semiconductor substrate including Al.

With this structure, the depletion mode transistor 20 is manufactured using a substrate having a relatively high rigidity. This allows for formation of the electron transit layer 56 composed of a nitride semiconductor including aluminum in a crystal composition and having a large thickness while limiting formation of cracks.

(8) The depletion mode transistor 20 may have an on-resistance that is greater than that of the enhancement mode transistor 30.

With this structure, the on-resistance of the depletion mode transistor 20 has a large proportion to the on-resistance of the nitride semiconductor device 10. Thus, the temperature dependence of the on-resistance of the nitride semiconductor device 10 is reduced effectively.

### Modified Examples of Depletion Mode Transistor

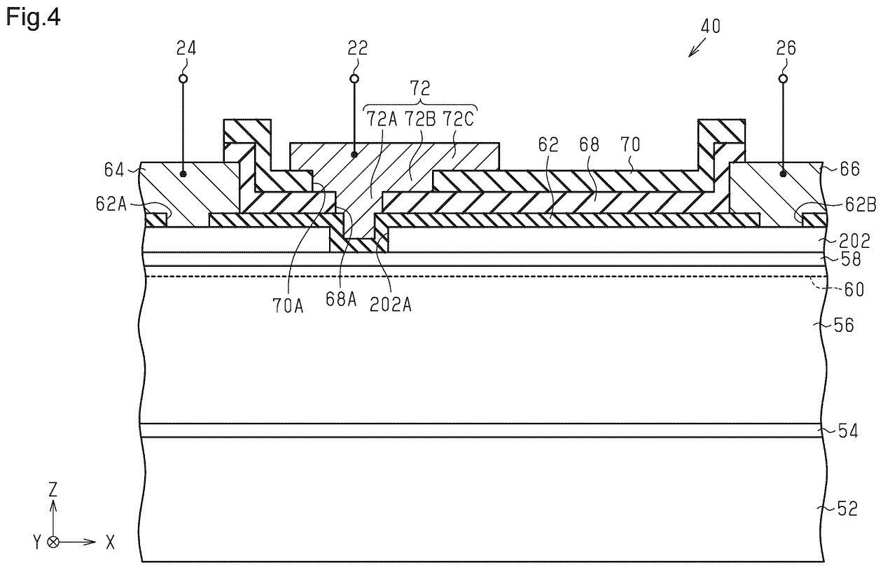

FIG. 4 is a schematic cross-sectional view showing a modified example of a depletion mode transistor 40. Instead of the depletion mode transistor 20 shown in FIG. 3, the depletion mode transistor 40 may be included in the nitride semiconductor device 10 and form the cascade connection.

The depletion mode transistor 40 includes a nitride semiconductor layer 202 formed on the electron supply layer 58 and including a donor impurity. The depletion mode transistor 40 differs from the depletion mode transistor 20, shown in FIG. 3, in that the depletion mode transistor 40 includes the nitride semiconductor layer 202 between the electron supply layer 58 and the gate insulation layer 62. In the depletion mode transistor 40 shown in FIG. 4, the same reference characters are given to those elements that are the same as the corresponding elements of the depletion mode transistor 20 shown in FIG. 3. Such elements will not be described in detail.

The nitride semiconductor layer 202 is formed on the electron supply layer 58. The nitride semiconductor layer 202 is composed of a nitride semiconductor including a donor impurity. In an example, the nitride semiconductor layer 202 may be a GaN layer including a donor impurity. In another example, the nitride semiconductor layer 202 may be an AlGaN layer including a donor impurity.

The nitride semiconductor layer 202 includes an opening 202A exposing the electron supply layer 58. As viewed from above in the Z-direction, the opening 202A is formed in the region of the opening 70A. The gate insulation layer 62 is formed on the nitride semiconductor layer 202 and in the opening 202A along the electron supply layer 58, which is exposed in the opening 202A. The opening 202A is filled with the gate insulation layer 62 and the gate electrode 72.

In this structure, the surface of the nitride semiconductor layer 202 is located distant from the 2DEG 60 so that occurrence of current collapse is limited.

### Application Example of Nitride Semiconductor Device

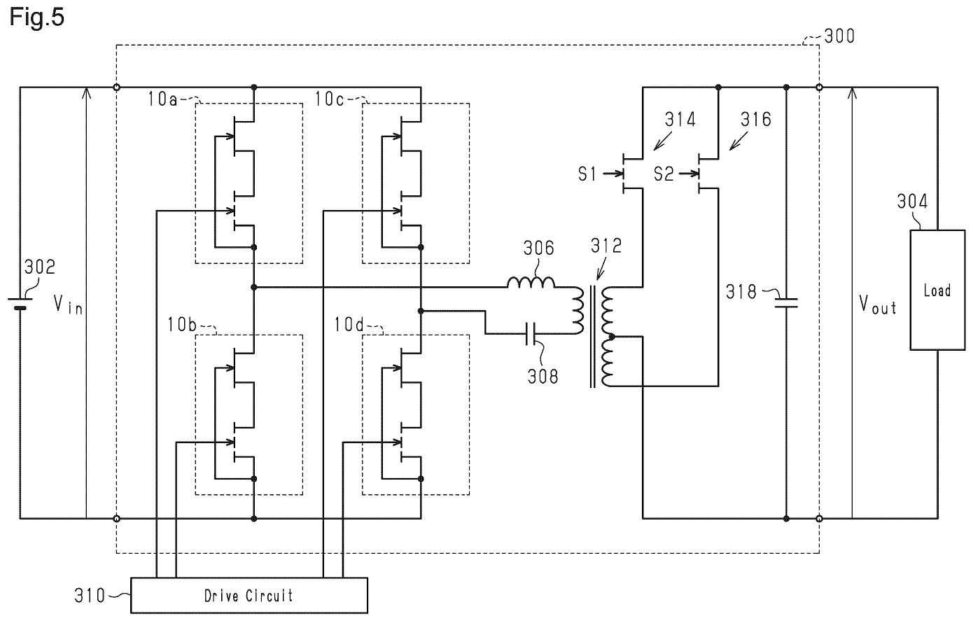

FIG. 5 is a schematic circuit diagram showing an application example of the nitride semiconductor device 10 according to the present disclosure. FIG. 5 shows an LLC resonant DC/DC converter 300 that uses the nitride semiconductor device 10 (refer to FIG. 1) of the present disclosure. The DC/DC converter 300 is configured to convert a DC input voltage Vᵢₙ, which is supplied from a DC input power source 302, into a DC output voltage Vₒᵤₜ, so that power is supplied to a load 304 (e.g., battery).

The DC/DC converter 300 may include four nitride semiconductor devices 10a, 10b, 10c, and 10d in a full-bridge configuration, a resonant inductor 306, and a resonant capacitor 308. Each of the nitride semiconductor devices 10a, 10b, 10c, and 10d corresponds to the nitride semiconductor device 10 (refer to FIG. 1) of the present disclosure. The resonant inductor 306 and the resonant capacitor 308 are respectively connected to the node between the nitride semiconductor device 10a and the nitride semiconductor device 10b and the node between the nitride semiconductor device 10c and the nitride semiconductor device 10d. In another example, instead of the four nitride semiconductor devices 10a, 10b, 10c, and 10d having a full-bridge configuration, the DC/DC converter 300 may include two nitride semiconductor devices 10 having a half-bridge configuration.

The nitride semiconductor devices 10a, 10b, 10c, and 10d perform switching in accordance with a drive signal received from a drive circuit 310 so that the DC input voltage Vᵢₙ is converted into AC voltage. The DC/DC converter 300 further includes a transformer 312 including a primary winding and a secondary winding. The AC voltage is supplied to the primary winding of the transformer 312.

The DC/DC converter 300 further includes rectifier elements 314 and 316 respectively connected to two ends of the secondary winding of the transformer 312 and a smoothing capacitor 318 connected to the center tap of the secondary winding of the transformer 312. In an example, the rectifier elements 314 and 316 may be a synchronous rectification transistor or a diode. As shown in FIG. 5, when the rectifier elements 314 and 316 are a synchronous rectification transistor, the rectifier elements 314 and 316 may be operated in accordance with respective signals S1 and S2. As a result, the AC voltage output from the transformer 312 is rectified and smoothed to produce DC output voltage Vₒᵤₜ.

When the depletion mode transistor 20 and/or the enhancement mode transistor 30 of the nitride semiconductor device 10 is a nitride semiconductor HEMT, the nitride semiconductor device 10 has satisfactory reverse recovery characteristic. This obtains the DC/DC converter 300 with relatively small loss.

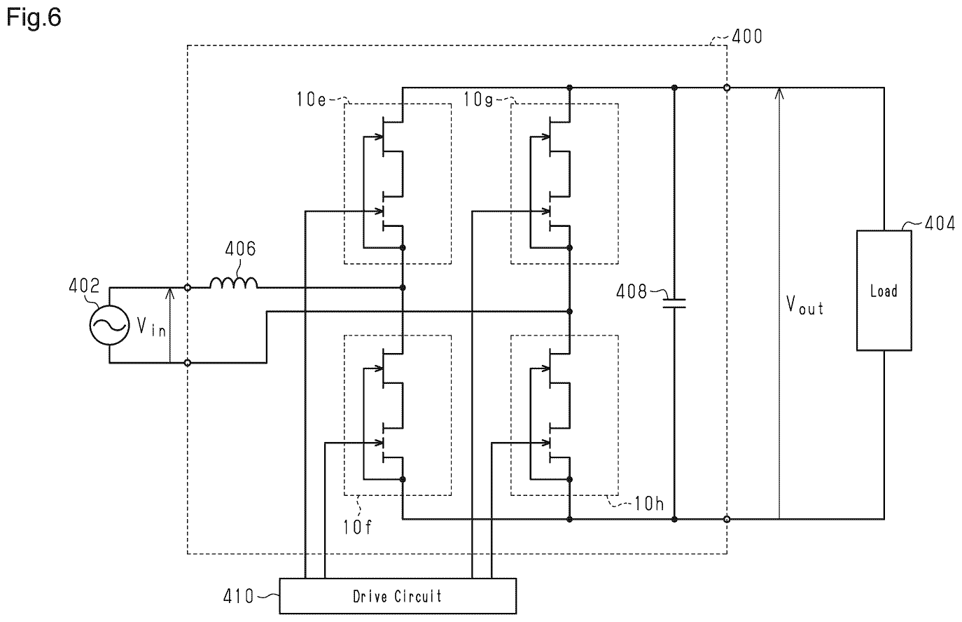

FIG. 6 is a schematic circuit diagram showing another application example of the nitride semiconductor device 10 according to the present disclosure. FIG. 6 shows a totem-pole power factor correction (PFC) circuit 400 that uses the nitride semiconductor device 10 (refer to FIG. 1) of the present disclosure. The PFC circuit 400 is configured to reduce the difference in phase between an input current and an AC input voltage Vᵢₙ supplied from an AC input power source 402 to improve the power factor. In the PFC circuit 400, the AC input voltage Vᵢₙ is converted into a DC output voltage Vₒᵤₜ so that DC output is supplied to a load 404.

The PFC circuit 400 may include a boost inductor 406, four nitride semiconductor devices 10e, 10f, 10g, and 10h, and a smoothing capacitor 408. Each of the nitride semiconductor devices 10e, 10f, 10g, and 10h corresponds to the nitride semiconductor device 10 (refer to FIG. 1) of the present disclosure. The inductor 406 is connected to the node between the nitride semiconductor device 10e and the nitride semiconductor device 10f. The AC input power source 402 is connected between the inductor 406 and the node between the nitride semiconductor device 10g and the nitride semiconductor device 10h. The nitride semiconductor devices 10e, 10f, 10g, and 10h perform switching in accordance with a drive signal received from a drive circuit 410 to perform synchronous rectification.

When the depletion mode transistor 20 and/or the enhancement mode transistor 30 of the nitride semiconductor device 10 is a nitride semiconductor HEMT, the nitride semiconductor device 10 has satisfactory reverse recovery characteristic. This obtains the PFC circuit 400 with relatively small loss.

The DC/DC converter 300, shown in FIG. 5, and the PFC circuit 400, shown in FIG. 6, are applicable to, for example, an onboard charger (OBC).

### Other Modified Examples

The embodiment and the modified examples described above may be modified as follows.

The gate layer 112 may include only one of the first extension 124 and the second extension 126 in addition to the ridge 122. In an example, the gate layer 112 may include the ridge 122 and the second extension 126 and exclude the first extension 124. In another example, the gate layer 112 may include the ridge 122 and exclude the first extension 124 and the second extension 126.

In the drawings, the gate electrode 114 is formed on a portion of the upper surface 112B of the gate layer 112. Instead, the gate electrode 114 may be formed to cover the entirety of the upper surface 112B of the gate layer 112.

The thickness of the electron supply layer 58 of the depletion mode transistor 20 may be less than or equal to the thickness of the second electron supply layer 108 of the enhancement mode transistor 30.

The electron transit layer 56 may be stacked on the substrate 52 via the buffer layer 54 or may be stacked on the substrate 52 without the buffer layer 54.

The electron transit layer 106 may be stacked on the substrate 102 via the buffer layer 104 or may be stacked on the substrate 102 without the buffer layer 104.

One or more of the various examples described in this specification may be combined within a range where there is no technical inconsistency.

In this specification, “at least one of A and B” should be understood to mean “only A, or only B, or both A and B.”

In the present disclosure, the term “on” includes the meaning of “above” in addition to the meaning of “on” unless otherwise clearly indicated in the context. Therefore, the phrase “first layer formed on second layer” is intended to mean that the first layer may be formed on the second layer in contact with the second layer in one embodiment and that the first layer may be located above the second layer without contacting the second layer in another embodiment. In other words, the term “on” does not exclude a structure in which another layer is formed between the first layer and the second layer. For example, a structure in which the electron supply layer 108 is formed on the electron transit layer 106 includes a structure in which an intermediate layer is arranged between the electron supply layer 108 and the electron transit layer 106 to stably form the 2DEG 110.

The directional terms used in the present disclosure such as “vertical,” “horizontal,” “above,” “below,” “top,” “bottom,” “frontward,” “backward,” “longitudinal,” “lateral,” “left,” “right,” “front,” and “back” will depend upon a particular orientation of the device being described and illustrated. The present disclosure may include various alternative orientations. Therefore, the directional terms should not be narrowly construed.

In an example, the Z-direction as referred to in the present disclosure does not necessarily have to be the vertical direction and does not necessarily have to fully conform to the vertical direction. In the structures according to the present disclosure (e.g., structure shown in FIG. 1), “upward” and “downward” in the Z-direction as referred to in the present description are not limited to “upward” and “downward” in the vertical direction. For example, the X-direction may conform to the vertical direction. The Y-direction may conform to the vertical direction.

### CLAUSES

The technical aspects that are understood from the present disclosure will hereafter be described. It should be noted that, for the purpose of facilitating understanding with no intention to limit, elements described in clauses are given the reference characters of the corresponding elements of the embodiments. The reference characters used as examples to facilitate understanding, and the elements in each clause are not limited to those elements given with the reference characters.

[Clause 1]

A nitride semiconductor device, including:
a depletion mode transistor (20) including a first gate terminal (22), a first source terminal (24), and a first drain terminal (26); and
an enhancement mode transistor (30) including a second gate terminal (32), a second source terminal (34), and a second drain terminal (36), in which
the second drain terminal (36) is connected to the first source terminal (24),
the second source terminal (34) is connected to the first gate terminal (22), and
the depletion mode transistor (20) includes
   an electron transit layer (56) composed of a nitride semiconductor including aluminum in a crystal composition, and
   an electron supply layer (58) formed on the electron transit layer (56) and composed of a nitride semiconductor including aluminum having a larger composition than that of the electron transit layer (56).

[Clause 2]

The nitride semiconductor device according to clause 1, in which
the electron transit layer (56) is formed of AlₓGa₁₋ₓN, and
the electron supply layer (58) is formed of Al_{y}Ga_{1-y}N,
where 0.1<x<0.2, 0.25<y<0.4, and x<y.

[Clause 3]

The nitride semiconductor device according to clause 1 or 2, in which the depletion mode transistor (40) further includes a nitride semiconductor layer (202) formed on the electron supply layer (58) and including a donor impurity.

[Clause 4]

The nitride semiconductor device according to any one of clauses 1 to 3, in which the enhancement mode transistor (30) includes
a second electron transit layer (106) composed of a nitride semiconductor having a band gap that is smaller than that of the electron transit layer (56) in the depletion mode transistor (20),
a second electron supply layer (108) formed on the second electron transit layer (106) and composed of a nitride semiconductor having a band gap that is larger than that of the second electron transit layer (106), and
a gate layer (112) formed on a portion of the second electron supply layer (108) and composed of a nitride semiconductor including an acceptor impurity.

[Clause 5]

The nitride semiconductor device according to clause 4, in which the electron supply layer (58) of the depletion mode transistor (20) is greater in thickness than the second electron supply layer (108) of the enhancement mode transistor (30).

[Clause 6]

The nitride semiconductor device according to clause 4 or 5, in which
the gate layer (112) has a thickness greater than or equal to 110 nm, and
the enhancement mode transistor (30) further includes a gate electrode (114) that forms a Schottky junction with the gate layer (112).

[Clause 7]

The nitride semiconductor device according to clause 6, in which the gate layer (112) includes
a ridge (122) including an upper surface (112B) on which the gate electrode (114) is formed, and
an extension (126) extending outward from the ridge (122) in plan view and having a thickness that is less than or equal to one-half of a thickness of the ridge.

[Clause 8]

The nitride semiconductor device according to any one of clauses 4 to 7, in which a gate-source voltage of the enhancement mode transistor (30) has a maximum rating that is greater than or equal to 8 V.

[Clause 9]

The nitride semiconductor device according to any one of clauses 1 to 3, in which the enhancement mode transistor (30) is a silicon MOSFET.

[Clause 10]

The nitride semiconductor device according to any one of clauses 1 to 9, in which each of the depletion mode transistor (20) and the enhancement mode transistor (30) further includes a Si substrate (52 or 102).

[Clause 11]

The nitride semiconductor device according to clause 10, in which each of the electron transit layer (56) and the second electron transit layer (106) is formed on the Si substrate (52 or 102).

[Clause 12]

The nitride semiconductor device according to clause 10 or 11, in which
each of the depletion mode transistor (20) and the enhancement mode transistor (30) further includes a buffer layer (54 or 104) formed on the Si substrate (52 or 102), and
each of the electron transit layer (56) and the second electron transit layer (106) is stacked on the Si substrate (52 or 102) via the buffer layer (54 or 104).

[Clause 13]

The nitride semiconductor device according to any one of clauses 1 to 9, in which
the depletion mode transistor (20) further includes a semiconductor substrate (52) including Al, and
the enhancement mode transistor (30) further includes a Si substrate (102).

[Clause 14]

The nitride semiconductor device according to clause 13, in which
the electron transit layer (56) is formed on the semiconductor substrate (52) including Al, and
the second electron transit layer (106) is formed on the Si substrate (102).

[Clause 15]

The nitride semiconductor device according to clause 13 or 14, in which
the depletion mode transistor (20) further includes a buffer layer (54) formed on the semiconductor substrate (52) including Al,
the enhancement mode transistor (30) further includes a second buffer layer (104) formed on the Si substrate (102),
the electron transit layer (56) is stacked on the semiconductor substrate (52) including Al via the buffer layer (54), and
the second electron transit layer (106) is stacked on the Si substrate (102) via the second buffer layer (104).

[Clause 16]

The nitride semiconductor device according to any one of clauses 1 to 15, in which a drain-source voltage of the depletion mode transistor (20) has a maximum rating that is greater than that of the enhancement mode transistor (30).

[Clause 17]

The nitride semiconductor device according to any one of clauses 1 to 16, in which
a drain-source voltage of the enhancement mode transistor (30) has a maximum rating that is greater than or equal to 30 V, and
a drain-source voltage of the depletion mode transistor (20) has a maximum rating that is greater than or equal to 500 V.

[Clause 18]

The nitride semiconductor device according to any one of clauses 1 to 17, in which the depletion mode transistor (20) has an on-resistance that is greater than that of the enhancement mode transistor (30).

[Clause 19]

The nitride semiconductor device according to any one of clauses 1 to 18, in which the depletion mode transistor (20) has an on-resistance that is more than ten times greater than that of the enhancement mode transistor (30).

[Clause 20]

The nitride semiconductor device according to any one of clauses 1 to 19, in which a drain-source voltage of the enhancement mode transistor (30) has a maximum rating that is less than or equal to 100 V.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A nitride semiconductor device, comprising:
a depletion mode transistor including a first gate terminal, a first source terminal, and a first drain terminal; and
an enhancement mode transistor including a second gate terminal, a second source terminal, and a second drain terminal, wherein
the second drain terminal is connected to the first source terminal,
the second source terminal is connected to the first gate terminal, and
the depletion mode transistor includes
an electron transit layer composed of a nitride semiconductor including aluminum in a crystal composition, and
an electron supply layer formed on the electron transit layer and composed of a nitride semiconductor including aluminum having a larger composition than that of the electron transit layer.

2. The nitride semiconductor device according to claim 1, wherein
the electron transit layer is formed of AlₓGa₁₋ₓN, and
the electron supply layer is formed of Al_{y}Ga_{1-y}N,
where 0.1<x<0.2, 0.25<y<0.4, and x<y.

3. The nitride semiconductor device according to claim 1, wherein the depletion mode transistor further includes a nitride semiconductor layer formed on the electron supply layer and including a donor impurity.

4. The nitride semiconductor device according to claim 1, wherein the enhancement mode transistor includes
a second electron transit layer composed of a nitride semiconductor having a band gap that is smaller than that of the electron transit layer in the depletion mode transistor,
a second electron supply layer formed on the second electron transit layer and composed of a nitride semiconductor having a band gap that is larger than that of the second electron transit layer, and
a gate layer formed on a portion of the second electron supply layer and composed of a nitride semiconductor including an acceptor impurity.

5. The nitride semiconductor device according to claim 4, wherein the electron supply layer of the depletion mode transistor is greater in thickness than the second electron supply layer of the enhancement mode transistor.

6. The nitride semiconductor device according to claim 4, wherein
the gate layer has a thickness greater than or equal to 110 nm, and
the enhancement mode transistor further includes a gate electrode that forms a Schottky junction with the gate layer.

7. The nitride semiconductor device according to claim 6, wherein the gate layer includes
a ridge including an upper surface on which the gate electrode is formed, and
an extension extending outward from the ridge in plan view and having a thickness that is less than or equal to one-half of a thickness of the ridge.

8. The nitride semiconductor device according to claim 4, wherein a gate-source voltage of the enhancement mode transistor has a maximum rating that is greater than or equal to 8 V.

9. The nitride semiconductor device according to claim 1, wherein the enhancement mode transistor is a silicon MOSFET.

10. The nitride semiconductor device according to claim 1, wherein each of the depletion mode transistor and the enhancement mode transistor further includes a Si substrate.

11. The nitride semiconductor device according to claim 1, wherein
the depletion mode transistor further includes a semiconductor substrate including Al, and
the enhancement mode transistor further includes a Si substrate.

12. The nitride semiconductor device according to claim 1, wherein a drain-source voltage of the depletion mode transistor has a maximum rating that is greater than that of the enhancement mode transistor.

13. The nitride semiconductor device according to claim 1, wherein
a drain-source voltage of the enhancement mode transistor has a maximum rating that is greater than or equal to 30 V, and
a drain-source voltage of the depletion mode transistor has a maximum rating that is greater than or equal to 500 V.

14. The nitride semiconductor device according to claim 1, wherein the depletion mode transistor has an on-resistance that is greater than that of the enhancement mode transistor.

15. The nitride semiconductor device according to claim 1, wherein the depletion mode transistor has an on-resistance that is more than ten times greater than that of the enhancement mode transistor.

16. The nitride semiconductor device according to claim 1, wherein a drain-source voltage of the enhancement mode transistor has a maximum rating that is less than or equal to 100 V.
